(19) United States
(12) Patent Application Publication
(10) Pub. No.: US 2019/0182990 A1
(43) Pub. Date: Jun. 13, 2019

(54) RACK COOLING SYSTEM

(71) Applicant: AURAS Technology Co., Ltd., New Taipei City (TW)

(72) Inventors: CHIEN-AN CHEN, New Taipei City (TW); MU-SHU FAN, New Taipei City (TW); CHIEN-YU CHEN, New Taipei City (TW); WEI-HAO CHEN, New Taipei City (TW); YU-JIE LIU, New Taipei City (TW)

(21) Appl. No.: 16/047,460

(22) Filed: Jul. 27, 2018

Related U.S. Application Data
(60) Provisional application No. 62/598,103, filed on Dec. 13, 2017.

(30) Foreign Application Priority Data
Jun. 11, 2018 (CN) 201810594685.5

(51) Int. Cl. H05K 7/20

(52) U.S. Cl. CPC H05K 7/20818; H05K 7/20736; H05K 7/20327; H05K 7/20318; H05K 7/20509

(57) ABSTRACT

A rack cooling system includes plural cold plates, a radiator, a coolant distribution unit, a fan and a manifold device. The plural cold plates correspond to plural electronic computing devices. The fan is used for driving the airflow. The manifold device is connected between the plural cold plates, the radiator and the coolant distribution unit. The fluid medium is circulated along a fluid loop that is defined by the plural cold plates, the radiator, the coolant distribution unit and the manifold device. Consequently, the heat from the plural electronic computing devices is dissipated away. The rack cooling system of the present invention has the elastically-changed architecture. Consequently, the rack cooling system can be applied to the racks with different heat dissipation demands while achieving the power-saving efficacy.

### CROSS-REFERENCE TO RELATED APPLICATION

This application claims priority to U.S. Provisional Patent Application No. 62/598,103 filed Dec. 13, 2017, the contents of which are incorporated herein by reference.

### FIELD OF THE INVENTION

The present invention relates to the field of heat dissipation, and more particularly to a cooling system.

### BACKGROUND OF THE INVENTION

With the increasing development and popularization of science and technology, various electronic computing devices such as network storage devices or servers have been essential parts of people's daily lives. Generally, these electronic computing devices are stored in a rack that is made of cold-rolled steel or alloy. Consequently, these electronic computing devices are protected from electromagnetic interference and arranged in an orderly and neat manner. Moreover, the electronic computing devices in the rack can be easily maintained or repaired in the future.

With the advent of big data and the Internet era, the processing power of the electronic computing device is increasing and the amount of the generated heat is large. It is important to effectively dissipate the heat from the electronic computing devices in the rack so as to increase the performance and the use lives of these electronic computing devices. In views of the power-saving benefit, it is important to achieve the proper heat dissipation efficacy with less power consumption.

FIG. 5 schematically illustrates the architecture of a conventional rack cooling system. As shown in FIG. 5, the conventional rack cooling system 7 comprises plural cold plates 71, a manifold device 72, a coolant distribution unit (CDU) 75 and a chiller 76. The manifold device 72 comprises a first fluid manifold 77 and a second fluid manifold 78. The plural cold plates 71 correspond to plural electronic computing devices 8 in a rack (not shown). For example, each cold plate 71 is in contact with the heat source of the corresponding electronic computing device 8. Each cold plate 71 comprises a cold plate inlet 711 and a cold plate outlet 712. The first fluid manifold 77 comprises a first manifold inlet 771 and plural first manifold outlets 772 corresponding to the plural cold plates 71. The second fluid manifold 78 comprises plural second manifold inlets 781 corresponding to the plural cold plates 71 and a second manifold outlet 782. The coolant distribution unit 75 comprises a first coolant distribution unit inlet 751, a first coolant distribution unit outlet 752, a second coolant distribution unit inlet 753 and a second coolant distribution unit outlet 754. The chiller 76 comprises a chiller inlet 761 and a chiller outlet 762.

The cold plate inlet 711 of each cold plate 71 is in fluid communication with the corresponding first manifold outlet 772 of the first fluid manifold 77. The cold plate outlet 712 of each cold plate 71 is in fluid communication with the corresponding second manifold inlet 781 of the second fluid manifold 78. The first coolant distribution unit inlet 751 of the coolant distribution unit 75 is in communication with the second manifold outlet 782 of the second fluid manifold 78. The first coolant distribution unit outlet 752 of the coolant distribution unit 75 is in communication with the first manifold inlet 771 of the first fluid manifold 77. In other words, a first fluid loop is defined by the plural cold plates 71, the manifold device 72 and the coolant distribution unit 75 collaboratively.

A first fluid medium (not shown) is filled in the first fluid loop. In the rack cooling system 7, the manifold device 72 is used for connecting associated conduits, homogenizing the first fluid medium and transferring the first fluid medium. The coolant distribution unit 75 is capable of uniformly or intelligently transferring the first fluid medium to the cold plates 71 through the first fluid manifold 77 of the manifold device 72 according to the practical requirements.

The chiller inlet 761 of the chiller 76 is in fluid communication with the second coolant distribution unit outlet 754 of the coolant distribution unit 75. The chiller outlet 762 of the chiller 76 is in fluid communication with the second coolant distribution unit inlet 753 of the coolant distribution unit 75. That is, a second fluid loop is defined by the chiller 76 and the coolant distribution unit 75 collaboratively. Moreover, a second fluid medium (not shown) is filled in the second fluid loop. The chiller 76 may be considered as a back-end heat dissipation mechanism for removing the heat from the first fluid medium that is transferred through the first fluid loop. That is, the first fluid medium in the first fluid loop and the second fluid medium in the second fluid loop exchange heat in the coolant distribution unit 75, wherein the first fluid medium and the second fluid medium are not mixed together.

The operations of the conventional rack cooling system 7 will be described as follows. When the first fluid medium flows through the cold plate 71 along the first fluid loop, the first fluid medium is heated by the heat source of the electronic computing device 8 corresponding to the cold plate 71. Then, the heated first fluid medium is transferred to the coolant distribution unit 75 through the second fluid manifold 78 of the manifold device 72. When the second fluid medium flows through the coolant distribution unit 75 along the second fluid loop, the second fluid medium is heated by the first fluid medium that is introduced into the coolant distribution unit 75. After the heated second fluid medium is outputted from the coolant distribution unit 75, the second fluid medium is transferred to the chiller 76 through the chiller inlet 761. Consequently, the second fluid medium is cooled down. After the second fluid medium is cooled down, the second fluid medium is transferred to the coolant distribution unit 75 again. Since the first fluid medium flowing into the coolant distribution unit 75 along the first fluid loop exchanges heat with the second fluid medium, the first fluid medium is cooled down. After the first fluid medium is cooled down, the first fluid medium is transferred to the cold plate 71 again through the first fluid manifold 77 of the manifold device 72. The above steps are repeatedly done to circulate the first fluid medium along the first fluid loop and circulate the second fluid medium along the second fluid loop. Since the heat of the electronic computing device 8 is dissipated to the low-temperature site, the efficacy of reducing the temperature of the first fluid medium is enhanced.

However, as the science and technology change very quickly, the racks 8 for storing the electronic computing devices have diversified specifications and designs according to different requirements. Even if the racks comply with the same specifications, the heat dissipation demands are not always identical. As known, the conventional rack cooling system 7 is monotonous and lacks elastic changes. For example, the racks belonging to some specifications have insufficient power dissipation capability. Although the racks belonging to some other specifications have sufficient power dissipation capability, these racks are not power-saving. In other words, the conventional rack cooling system 7 needs to be further improved.

### SUMMARY OF THE INVENTION

For solving the drawbacks of the conventional technologies, the present invention provides a rack cooling system. The rack cooling system has the elastically-changed architecture. Consequently, the rack cooling system can be applied to the racks with different heat dissipation demands while achieving the power-saving efficacy.

In accordance with an aspect of the present invention, there is provided a rack cooling system for a rack. Moreover, plural electronic computing devices are installed in the rack. The rack cooling system includes plural cold plates corresponding to the plural electronic computing devices, a radiator, a coolant distribution unit, at least one fan and a manifold device. A fluid medium flows through the radiator to exchange heat. After the fluid medium is introduced into the coolant distribution unit, the fluid medium is distributed by the coolant distribution unit. The at least one fan is used for driving an airflow. The manifold device is connected between the plural cold plates, the radiator and the coolant distribution unit. The fluid medium is circulated through the plural cold plates, the radiator, the coolant distribution unit and the manifold device. Consequently, the heat from the plural electronic computing devices is dissipated away.

In an embodiment, the manifold device includes a first fluid manifold and a second fluid manifold. The first fluid manifold includes a first manifold inlet and plural first manifold outlets corresponding to the plural cold plates. The second fluid manifold includes a second manifold outlet and plural second manifold inlets corresponding to the plural cold plates.

In an embodiment, each of the plural cold plates includes a cold plate inlet and a cold plate outlet. The cold plate inlet is in fluid communication with the corresponding one of the plural first manifold outlets. The cold plate outlet is in fluid communication with the corresponding one of the plural second manifold inlets. After the fluid medium is outputted from the cold plate through the cold plate outlet, the fluid medium is transferred to the second fluid manifold through the corresponding one of the plural second manifold inlets. After the fluid medium is outputted from the first fluid manifold through the corresponding one of the plural first manifold outlets, the fluid medium is transferred to the cold plate through the cold plate inlet.

In an embodiment, the radiator includes a radiator inlet and a radiator outlet, and the coolant distribution unit includes a first coolant distribution unit inlet and a first coolant distribution unit outlet. The radiator inlet is in fluid communication with the second manifold outlet. The radiator outlet is in fluid communication with the first coolant distribution unit inlet. The first coolant distribution unit outlet is in communication with the first manifold inlet. After the fluid medium is outputted from the second fluid manifold through the second manifold outlet, the fluid medium is transferred to the radiator through the radiator inlet. After the fluid medium is outputted from the radiator through the radiator outlet, the fluid medium is transferred to the coolant distribution unit through the first coolant distribution unit inlet. After the fluid medium is outputted from the coolant distribution unit through the first coolant distribution unit outlet, the fluid medium is transferred to the first fluid manifold through the first manifold inlet.

In an embodiment, the radiator includes a radiator inlet and a radiator outlet, and the coolant distribution unit includes a first coolant distribution unit inlet and a first coolant distribution unit outlet. The radiator inlet is in fluid communication with the first coolant distribution unit outlet. The radiator outlet is in fluid communication with the first manifold inlet. The first coolant distribution unit inlet is in communication with the second manifold outlet. After the fluid medium is outputted from the second fluid manifold through the second manifold outlet, the fluid medium is transferred to the coolant distribution unit through the first coolant distribution unit inlet. After the fluid medium is outputted from the coolant distribution unit through the first coolant distribution unit outlet, the fluid medium is transferred to the radiator through the radiator inlet. After the fluid medium is outputted from the radiator through the radiator outlet, the fluid medium is transferred to the first fluid manifold through the first manifold inlet.

In an embodiment, the rack cooling system further includes a chiller with a chiller inlet and a chiller outlet, and the coolant distribution unit includes a second coolant distribution unit inlet and a second coolant distribution unit outlet. The chiller inlet is in fluid communication with the second coolant distribution unit outlet. The chiller outlet is in fluid communication with the second coolant distribution unit inlet. After an additional fluid medium is outputted from the coolant distribution unit through the second coolant distribution unit outlet, the additional fluid medium is transferred to the chiller through the chiller inlet. After the additional fluid medium is outputted from the chiller through the chiller outlet, the additional fluid medium is transferred to the coolant distribution unit through the second coolant distribution unit inlet.

Preferably, the at least one fan is arranged near the radiator, or the at least one fan is arranged near the plural cold plates.

After the fluid medium is outputted from one of the plural cold plates and before the fluid medium is introduced into the radiator, the fluid medium has a first average temperature. After the fluid medium is outputted from the radiator and before the fluid medium is transferred to the one of the plural cold plates, the fluid medium has a second average temperature. Consequently, the first average temperature is higher than the second average temperature.

After the fluid medium is outputted from one of the plural cold plates and before the fluid medium is introduced into the coolant distribution unit, the fluid medium has a first average temperature. After the fluid medium is outputted from the coolant distribution unit and before the fluid medium is transferred to the one of the plural cold plates, the fluid medium has a second average temperature. Consequently, the first average temperature is higher than the second average temperature.

In an embodiment, each of the plural electronic computing devices is a server or a network storage device.

In an embodiment, the radiator is a condenser.

Due to the arrangement of the radiator, the rack cooling system of the present invention has the elastically-changed architecture. Consequently, the rack cooling system can be applied to the racks with different heat dissipation demands while achieving the power-saving efficacy.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 schematically illustrates the architecture of a rack cooling system according to a first embodiment of the present invention;

FIG. 2 schematically illustrates the architecture of a rack cooling system according to a second embodiment of the present invention;

FIG. 3 schematically illustrates the architecture of a rack cooling system according to a third embodiment of the present invention;

FIG. 4 schematically illustrates the architecture of a rack cooling system according to a fourth embodiment of the present invention; and

FIG. 5 schematically illustrates the architecture of a conventional rack cooling system.

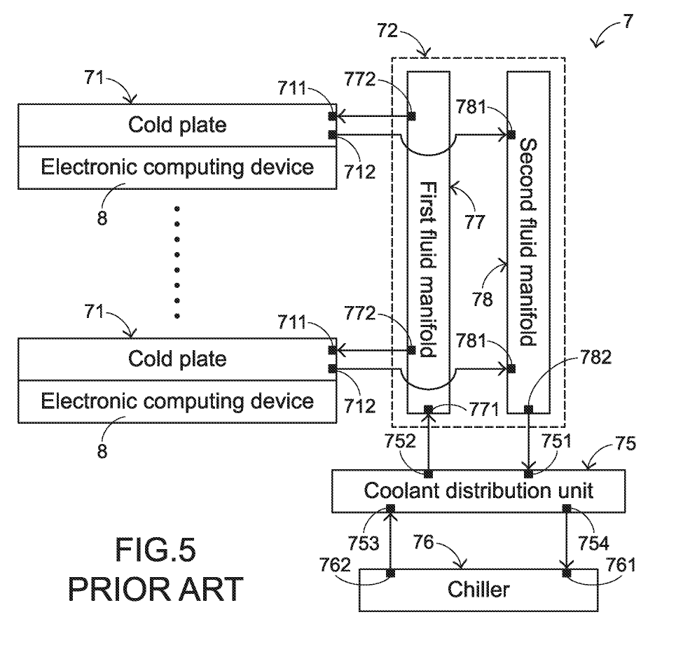

### DETAILED DESCRIPTION OF THE PREFERRED EMBODIMENT

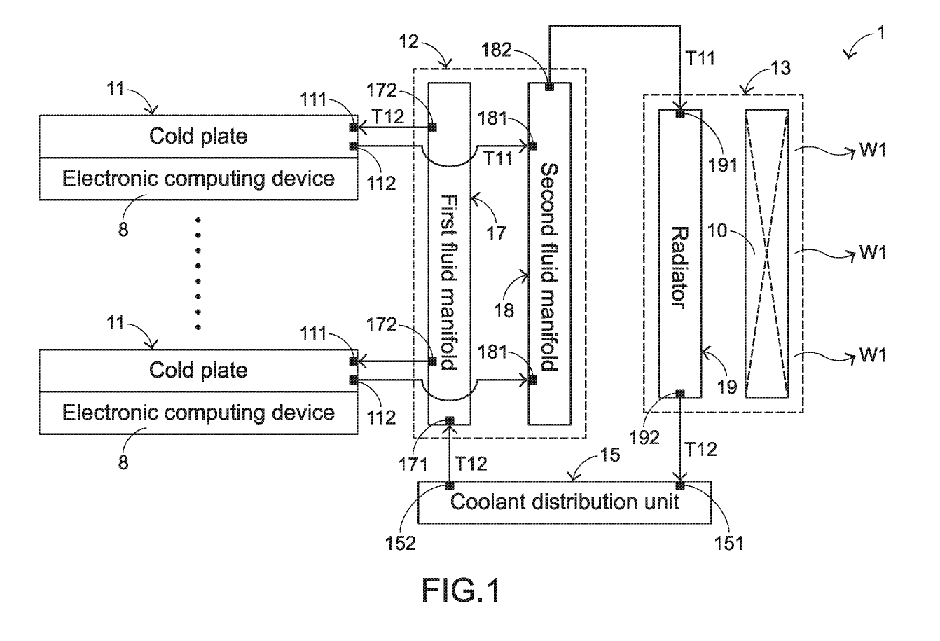

FIG. 1 schematically illustrates the architecture of a rack cooling system according to a first embodiment of the present invention. As shown in FIG. 1, the rack cooling system 1 comprises plural cold plates 11, a manifold device 12, a system cooling unit 13 and a coolant distribution unit (CDU) 15. The manifold device 12 comprises a first fluid manifold 17 and a second fluid manifold 18. The plural cold plates 11 correspond to plural electronic computing devices 8 in a rack (not shown). For example, the electronic computing devices 8 are servers or network storage devices. Each cold plate 11 is in contact with the heat source of the corresponding electronic computing device 8. Preferably but not exclusively, the cold plate 11 and the corresponding electronic computing device 8 are included in the same chassis (not shown). Each cold plate 11 comprises a cold plate inlet 111 and a cold plate outlet 112. The first fluid manifold 17 comprises a first manifold inlet 171 and plural first manifold outlets 172 corresponding to the plural cold plates 11. The second fluid manifold 18 comprises plural second manifold inlets 181 corresponding to the plural cold plates 11 and a second manifold outlet 182. The coolant distribution unit 15 comprises a coolant distribution unit inlet 151 and a coolant distribution unit outlet 152.

In the first embodiment, the system cooling unit 13 comprises a radiator 19 and a fan 10. Preferably but not exclusively, the radiator 19 is a condenser. The condenser is a heat exchanger for transforming gas or vapor into liquid so as to provide cooling efficacy. In addition, the heat from the heat pipe (not shown) of the condenser can be quickly radiated to the ambient air of the radiator 19. Consequently, the heat is dissipated away. The fan 10 is used for driving the airflow W1 to remove heat from the ambient air of the radiator 19. Preferably but not exclusively, the fan 10 is arranged near the radiator 19. The radiator 19 comprises a radiator inlet 191 and a radiator outlet 192.

The cold plate inlet 111 of each cold plate 11 is in fluid communication with the corresponding first manifold outlet 172 of the first fluid manifold 17. The cold plate outlet 112 of each cold plate 11 is in fluid communication with the corresponding second manifold inlet 181 of the second fluid manifold 18. The radiator inlet 191 of the radiator 19 is in fluid communication with the second manifold outlet 182 of the second fluid manifold 18. The radiator outlet 192 of the radiator 19 is in fluid communication with the coolant distribution unit inlet 151 of the coolant distribution unit 15. The coolant distribution unit outlet 152 of the coolant distribution unit 15 is in communication with the first manifold inlet 171 of the first fluid manifold 17. In other words, a fluid loop is defined by the plural cold plates 11, the manifold device 12, the radiator 19 and the coolant distribution unit 15 collaboratively.

Preferably but not exclusively, the relationship of each fluid communication may be established through the connection of an associated conduit (not shown). Moreover, a fluid medium (not shown) is filled in the fluid loop. The fluid medium is a liquid medium, a gaseous medium or the mixture of the liquid medium and the gaseous medium. In the rack cooling system 1, the manifold device 12 is used for connecting associated conduits, homogenizing the fluid medium and transferring the fluid medium. After the fluid medium is introduced into the coolant distribution unit 15, the fluid medium is distributed by the coolant distribution unit 15. For example, the fluid medium is uniformly or intelligently transferred from the coolant distribution unit 15 to the cold plates 11 through the first fluid manifold 17 of the manifold device 12 according to the practical requirements. Preferably but not exclusively, the coolant distribution unit 15 is capable of monitoring the heat dissipation performance in real time and automatically adjusting the optimal heat dissipation performance.

The operations of the rack cooling system 1 according to the first embodiment of the present invention will be described as follows. When the fluid medium flows through the cold plate 11, the fluid medium is heated by the heat source of the electronic computing device 8 corresponding to the cold plate 11. After the fluid medium is outputted from the cold plate 11 through the cold plate outlet 112, the fluid medium is transferred to the second fluid manifold 18 through the corresponding second manifold inlet 181. After the fluid medium is outputted from the second fluid manifold 18 through the second manifold outlet 182, the fluid medium is transferred to the radiator 19 through the radiator inlet 191. As mentioned above, the fluid medium flowing into the radiator 19 exchanges heat with the radiator 19, and thus the fluid medium is cooled down. At the same time, the fan 10 of the system cooling unit 13 drives the airflow W1 to remove the heat from the ambient air of the radiator 19. After the fluid medium is cooled down by the radiator 19, the fluid medium is outputted from the radiator 19 through the radiator outlet 192. Then, the fluid medium is transferred to the coolant distribution unit 15 through the coolant distribution unit inlet 151. After the fluid medium is outputted from the coolant distribution unit 15 through the coolant distribution unit outlet 152, the fluid medium is transferred to the first fluid manifold 17 through the first manifold inlet 171. After the fluid medium is outputted from the first fluid manifold 17 through the first manifold outlet 172, the fluid medium is transferred to the cold plate 11 again through the corresponding cold plate inlet 111. The above steps are repeatedly done to circulate the fluid medium along the fluid loop. Since the heat of the electronic computing device 8 is dissipated to the low-temperature site, the efficacy of reducing the temperature of the fluid medium is enhanced.

For example, after the fluid medium is outputted from the cold plate 11 and before the fluid medium is introduced into the radiator 19, the fluid medium has an average temperature T11. After the fluid medium is outputted from the radiator 19 and before the fluid medium is transferred to the cold plate 11, the fluid medium has an average temperature T12. Consequently, the average temperature T12 is lower than the average temperature T11.

In comparison with the conventional rack cooling system 7, the chiller of the rack cooling system 1 of the first embodiment does not consume much energy. In other words, the rack cooling system of the present invention has the power-saving benefit. In addition, the rack cooling system of this embodiment is suitably installed in the rack with lower heat dissipation demand.

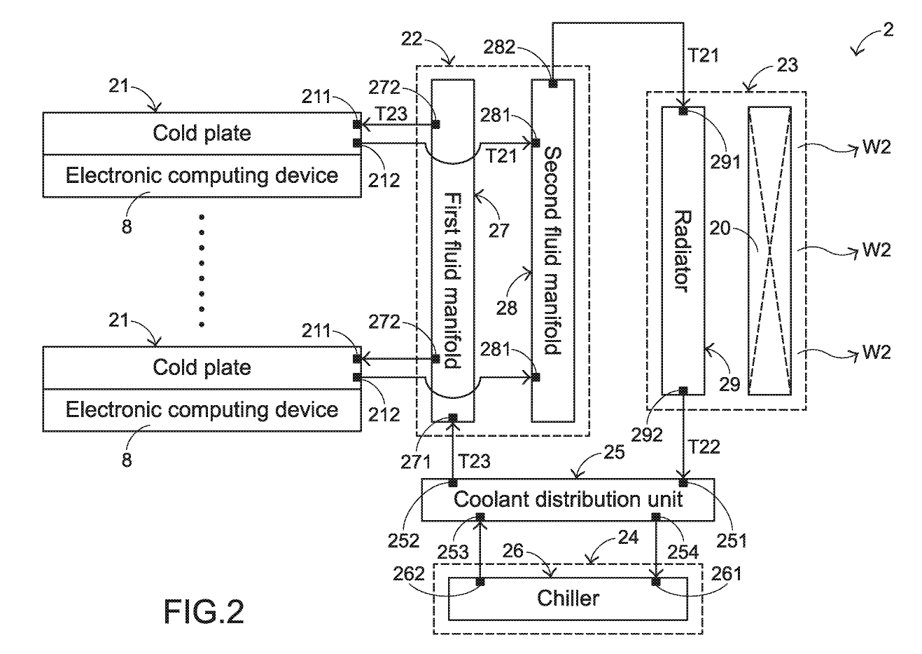

FIG. 2 schematically illustrates the architecture of a rack cooling system according to a second embodiment of the present invention. As shown in FIG. 2, the rack cooling system 2 comprises plural cold plates 21, a manifold device 22, a first system cooling unit 23, a second system cooling unit 24 and a coolant distribution unit (CDU) 25. The manifold device 22 comprises a first fluid manifold 27 and a second fluid manifold 28. The plural cold plates 21 correspond to plural electronic computing devices 8 in a rack (not shown). For example, the electronic computing devices 8 are servers or network storage devices. Each cold plate 21 is in contact with the heat source of the corresponding electronic computing device 8. Preferably but not exclusively, the cold plate 21 and the corresponding electronic computing device 8 are included in the same chassis (not shown). Each cold plate 21 comprises a cold plate inlet 211 and a cold plate outlet 212. The first fluid manifold 27 comprises a first manifold inlet 271 and plural first manifold outlets 272 corresponding to the plural cold plates 21. The second fluid manifold 28 comprises plural second manifold inlets 281 corresponding to the plural cold plates 21 and a second manifold outlet 282. The coolant distribution unit 25 comprises a first coolant distribution unit inlet 251, a first coolant distribution unit outlet 252, a second coolant distribution unit inlet 253 and a second coolant distribution unit outlet 254.

In the second embodiment, the first system cooling unit 23 comprises a radiator 29 and a fan 20. For example, the radiator 29 is a condenser. Preferably but not exclusively, the second system cooling unit 24 comprises a chiller 26. The condenser is a heat exchanger for transforming gas or vapor into liquid so as to provide cooling efficacy. In addition, the heat from the heat pipe (not shown) of the condenser can be quickly radiated to the ambient air of the radiator 29. Consequently, the heat is dissipated away. The fan 20 is used for driving the airflow W2 to remove heat from the ambient air of the radiator 29. Preferably but not exclusively, the fan 20 is arranged near the radiator 29. The radiator 29 comprises a radiator inlet 291 and a radiator outlet 292. The chiller 26 comprises a chiller inlet 261 and a chiller outlet 262.

The cold plate inlet 211 of each cold plate 21 is in fluid communication with the corresponding first manifold outlet 272 of the first fluid manifold 27. The cold plate outlet 212 of each cold plate 21 is in fluid communication with the corresponding second manifold inlet 281 of the second fluid manifold 28. The radiator inlet 291 of the radiator 29 is in fluid communication with the second manifold outlet 282 of the second fluid manifold 28. The radiator outlet 292 of the radiator 29 is in fluid communication with the first coolant distribution unit inlet 251 of the coolant distribution unit 25. The first coolant distribution unit outlet 252 of the coolant distribution unit 25 is in communication with the first manifold inlet 271 of the first fluid manifold 27. In other words, a first fluid loop is defined by the plural cold plates 21, the manifold device 22, the radiator 29 and the coolant distribution unit 25 collaboratively.

Preferably but not exclusively, the relationship of each fluid communication may be established through the connection of an associated conduit (not shown). Moreover, a first fluid medium (not shown) is filled in the first fluid loop. The first fluid medium is a liquid medium, a gaseous medium or the mixture of the liquid medium and the gaseous medium. In the rack cooling system 2, the manifold device 22 is used for connecting associated conduits, homogenizing the first fluid medium and transferring the first fluid medium. After the first fluid medium is introduced into the coolant distribution unit 25, the first fluid medium is distributed by the coolant distribution unit 25. For example, the first fluid medium is uniformly or intelligently transferred from the coolant distribution unit 25 to the cold plates 21 through the first fluid manifold 27 of the manifold device 22 according to the practical requirements. Preferably but not exclusively, the coolant distribution unit 25 is capable of monitoring the heat dissipation performance in real time and automatically adjusting the optimal heat dissipation performance.

The chiller inlet 261 of the chiller 26 is in fluid communication with the second coolant distribution unit outlet 254 of the coolant distribution unit 25. The chiller outlet 262 of the chiller 26 is in fluid communication with the second coolant distribution unit inlet 253 of the coolant distribution unit 25. That is, a second fluid loop is defined by the chiller 26 and the coolant distribution unit 25 collaboratively. Moreover, a second fluid medium (not shown) is filled in the second fluid loop. The second fluid medium is a liquid medium, a gaseous medium or the mixture of the liquid medium and the gaseous medium. The chiller 26 may be considered as a cooling mechanism for removing the heat from the first fluid medium that is transferred through the first fluid loop. That is, the first fluid medium in the first fluid loop and the second fluid medium in the second fluid loop exchange heat in the coolant distribution unit 25, wherein the first fluid medium and the second fluid medium are not mixed together

The operations of the rack cooling system 2 according to the second embodiment of the present invention will be described as follows. When the first fluid medium flows through the cold plate 21 along the first fluid loop, the first fluid medium is heated by the heat source of the electronic computing device 8 corresponding to the cold plate 21. After the heated first fluid medium is outputted from the cold plate 21 through the cold plate outlet 212, the first fluid medium is transferred to the second fluid manifold 28 through the corresponding second manifold inlet 281. After the first fluid medium is outputted from the second fluid manifold 28 through the second manifold outlet 282, the first fluid medium is transferred to the radiator 29 through the radiator inlet 291. As mentioned above, the first fluid medium flowing into the radiator 29 exchanges heat with the radiator 29, and thus the first fluid medium is cooled down in a first stage. At the same time, the fan 20 of the first system cooling unit 23 drives the airflow W2 to remove the heat from the ambient air of the radiator 29. After the first fluid medium is cooled down by the radiator 29 in the first stage, the first fluid medium is outputted from the radiator 29 through the radiator outlet 292. Then, the first fluid medium is transferred to the coolant distribution unit 25 through the first coolant distribution unit inlet 251.

Similarly, when the second fluid medium flows through the coolant distribution unit 25 along the second fluid loop, the second fluid medium is heated by the first fluid medium that is introduced into the coolant distribution unit 25. After the heated second fluid medium is outputted from the coolant distribution unit 25 through the second coolant distribution unit outlet 254, the second fluid medium is transferred to the chiller 26 through the chiller inlet 261. Consequently, the second fluid medium is cooled down. After the second fluid medium is cooled down, the second fluid medium is outputted from the chiller 26 through the chiller outlet 262. Moreover, the cooled second fluid medium is transferred to the coolant distribution unit 25 again through the second coolant distribution unit inlet 253. Since the first fluid medium flowing into the coolant distribution unit 25 along the first fluid loop exchanges heat with the second fluid medium, the first fluid medium is cooled down in a second stage.

After the first fluid medium is cooled down in the second stage, the first fluid medium is outputted from the coolant distribution unit 25 through the coolant distribution unit outlet 252. Then, the first fluid medium is transferred to the first fluid manifold 27 through the first manifold inlet 271. After the first fluid medium is outputted from the first fluid manifold 27 through the first manifold outlet 272, the first fluid medium is transferred to the cold plate 21 again through the corresponding cold plate inlet 211. The above steps are repeatedly done to circulate the first fluid medium along the first fluid loop and circulate the second fluid medium along the second fluid loop. Since the heat of the electronic computing device 8 is dissipated to the low-temperature site, the efficacy of reducing the temperature of the first fluid medium is enhanced.

For example, after the fluid medium is outputted from the cold plate 21 and before the fluid medium is introduced into the radiator 29, the first fluid medium has an average temperature T21. After the first fluid medium is outputted from the radiator 29 and before the first fluid medium is transferred to the coolant distribution unit 25, the first fluid medium has an average temperature T22. After the first fluid medium is outputted from the coolant distribution unit 25 and before the first fluid medium is transferred to the cold plate 21, the first fluid medium has an average temperature T23. Consequently, the average temperature T23 is lower than the average temperature T22, and the average temperature T22 is lower than the average temperature T21.

In comparison with the conventional rack cooling system 7, the rack cooling system 2 of the second embodiment is further equipped with the first system cooling unit 23. After the heated first fluid medium is outputted from the cold plate 21, the first fluid medium is cooled down in the first stage. Consequently, the heat dissipation loading and the power consumption amount of the second system cooling unit 24 are reduced. In other words, the rack cooling system 2 of this embodiment is suitably installed in the rack with higher heat dissipation demand. Preferably but not exclusively, the heat dissipation capacity of the first system cooling unit 23 takes about 20 percent of the overall heat dissipation capacity, and the heat dissipation capacity of the second system cooling unit 24 takes about 80 percent of the overall heat dissipation capacity.

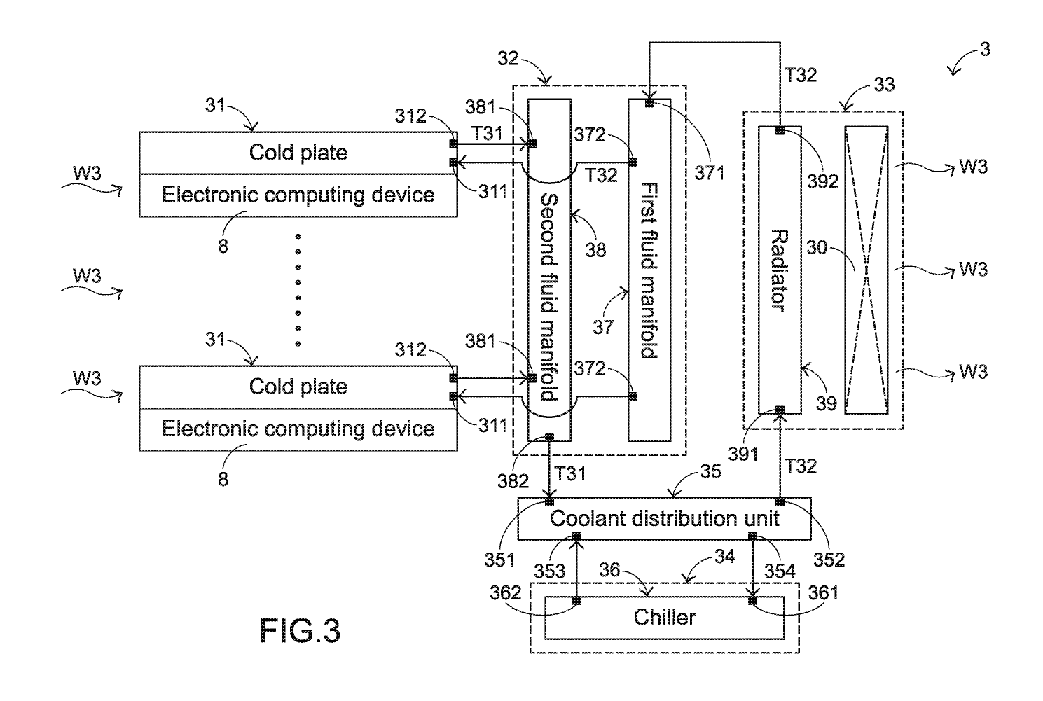

FIG. 3 schematically illustrates the architecture of a rack cooling system according to a third embodiment of the present invention. As shown in FIG. 3, the rack cooling system 3 comprises plural cold plates 31, a manifold device 32, a first system cooling unit 33, a second system cooling unit 34 and a coolant distribution unit (CDU) 35. The manifold device 32 comprises a first fluid manifold 37 and a second fluid manifold 38. The plural cold plates 31 correspond to plural electronic computing devices 8 in a rack (not shown). For example, the electronic computing devices 8 are servers or network storage devices. Each cold plate 31 is in contact with the heat source of the corresponding electronic computing device 8. Preferably but not exclusively, the cold plate 31 and the corresponding electronic computing device 8 are included in the same chassis (not shown). Each cold plate 31 comprises a cold plate inlet 311 and a cold plate outlet 312. The first fluid manifold 37 comprises a first manifold inlet 371 and plural first manifold outlets 372 corresponding to the plural cold plates 31. The second fluid manifold 38 comprises plural second manifold inlets 381 corresponding to the plural cold plates 31 and a second manifold outlet 382. The coolant distribution unit 35 comprises a first coolant distribution unit inlet 351, a first coolant distribution unit outlet 352, a second coolant distribution unit inlet 353 and a second coolant distribution unit outlet 354.

In the third embodiment, the first system cooling unit 33 comprises a radiator 39 and a fan 30. For example, the radiator 39 is a condenser. Preferably but not exclusively, the second system cooling unit 34 comprises a chiller 36. The condenser is a heat exchanger for transforming gas or vapor into liquid so as to provide cooling efficacy. In addition, the heat from the heat pipe (not shown) of the condenser can be quickly radiated to the ambient air of the radiator 39. Consequently, the heat is dissipated away. The fan 30 is used for driving the airflow W3 to remove heat from the ambient air of the radiator 39. Preferably but not exclusively, the fan 30 is arranged near the radiator 39. The radiator 39 comprises a radiator inlet 391 and a radiator outlet 392. The chiller 36 comprises a chiller inlet 362 and a chiller outlet 362.

The cold plate inlet 311 of each cold plate 31 is in fluid communication with the corresponding first manifold outlet 372 of the first fluid manifold 37. The cold plate outlet 312 of each cold plate 31 is in fluid communication with the corresponding second manifold inlet 381 of the second fluid manifold 38. The first coolant distribution unit inlet 351 of the coolant distribution unit 35 is in fluid communication with the second manifold outlet 382 of the second fluid manifold 38. The first coolant distribution unit outlet 352 of the coolant distribution unit 35 is in communication with the radiator inlet 391 of the radiator 39. The radiator outlet 392 of the radiator 39 is in fluid communication with the first manifold inlet 371 of the first fluid manifold 37. In other words, a first fluid loop is defined by the plural cold plates 31, the manifold device 32, the coolant distribution unit 35 and the radiator 39 collaboratively.

Preferably but not exclusively, the relationship of each fluid communication may be established through the connection of an associated conduit (not shown). Moreover, a first fluid medium (not shown) is filled in the first fluid loop. The first fluid medium is a liquid medium, a gaseous medium or the mixture of the liquid medium and the gaseous medium. In the rack cooling system 3, the manifold device 32 is used for connecting associated conduits, homogenizing the first fluid medium and transferring the first fluid medium. After the first fluid medium is introduced into the coolant distribution unit 35, the first fluid medium is distributed by the coolant distribution unit 35. For example, the first fluid medium is uniformly or intelligently transferred from the coolant distribution unit 35 to the radiator 39 according to the practical requirements. Preferably but not exclusively, the coolant distribution unit 35 is capable of monitoring the heat dissipation performance in real time and automatically adjusting the optimal heat dissipation performance.

The chiller inlet 361 of the chiller 36 is in fluid communication with the second coolant distribution unit outlet 354 of the coolant distribution unit 35. The chiller outlet 362 of the chiller 36 is in fluid communication with the second coolant distribution unit inlet 353 of the coolant distribution unit 35. That is, a second fluid loop is defined by the chiller 36 and the coolant distribution unit 35 collaboratively. Moreover, a second fluid medium (not shown) is filled in the second fluid loop. The second fluid medium is a liquid medium, a gaseous medium or the mixture of the liquid medium and the gaseous medium. The chiller 36 is considered as a cooling mechanism for removing the heat from the first fluid medium that is transferred through the first fluid loop. That is, the first fluid medium in the first fluid loop and the second fluid medium in the second fluid loop exchange heat in the coolant distribution unit 35, wherein the first fluid medium and the second fluid medium are not mixed together.

The operations of the rack cooling system 3 according to the third embodiment of the present invention will be described as follows. When the first fluid medium flows through the cold plate 31 along the first fluid loop, the first fluid medium is heated by the heat source of the electronic computing device 8 corresponding to the cold plate 31. After the heated first fluid medium is outputted from the cold plate 31 through the cold plate outlet 312, the first fluid medium is transferred to the second fluid manifold 38 through the corresponding second manifold inlet 381. After the first fluid medium is outputted from the second fluid manifold 38 through the second manifold outlet 382, the first fluid medium is transferred to the coolant distribution unit 35 through the first coolant distribution unit inlet 351. Similarly, when the second fluid medium flows through the coolant distribution unit 35 along the second fluid loop, the second fluid medium is heated by the first fluid medium that is introduced into the coolant distribution unit 35. After the heated second fluid medium is outputted from the coolant distribution unit 35 through the second coolant distribution unit outlet 354, the second fluid medium is transferred to the chiller 36 through the chiller inlet 361. Consequently, the second fluid medium is cooled down. After the second fluid medium is cooled down, the cooled second fluid medium is outputted from the chiller 36 through the chiller outlet 362. Moreover, the second fluid medium is transferred to the coolant distribution unit 35 again through the second coolant distribution unit inlet 353. Since the first fluid medium flowing into the coolant distribution unit 35 along the first fluid loop exchanges heat with the second fluid medium, the first fluid medium is cooled down.

Moreover, after the first fluid medium flowing along the first fluid loop is cooled down by the coolant distribution unit 35, the first fluid medium is outputted from the coolant distribution unit 35 through the coolant distribution unit outlet 352. Then, the first fluid medium is transferred to the radiator 39 through the radiator inlet 391. After the first fluid medium is outputted from the radiator 39 through the radiator outlet 39, the first fluid medium is transferred to the first fluid manifold 37 through the first manifold inlet 371. After the first fluid medium is outputted from the first fluid manifold 37 through the first manifold outlet 372, the fluid medium is transferred to the cold plate 31 again through the corresponding cold plate inlet 311. The above steps are repeatedly done to circulate the first fluid medium along the first fluid loop and circulate the second fluid medium along the second fluid loop. Since the heat of the electronic computing device 8 is dissipated to the low-temperature site, the efficacy of reducing the temperature of the first fluid medium is enhanced. As mentioned above, the radiator 39 has the ability to reduce the temperature of the ambient air. Moreover, the fan 30 is cooperatively used to drive the airflow W3. Since the overall temperature of the environment around the rack cooling system 3 is reduced, the efficacy of dissipating the heat of the air is achieved.

For example, after the first fluid medium is outputted from the cold plate 31 and before the first fluid medium is introduced into the coolant distribution unit 35, the fluid medium has an average temperature T31. After the first fluid medium is outputted from the coolant distribution unit 35 and before the first fluid medium is transferred to the cold plate 31, the first fluid medium has an average temperature T32. Consequently, the average temperature T32 is lower than the average temperature T31.

In comparison with the conventional rack cooling system 7, the rack cooling system 3 of the third embodiment is further equipped with the first system cooling unit 33 to cool the ambient air. In other words, the rack cooling system 3 of this embodiment is suitably installed in the rack with higher heat dissipation demand. Preferably but not exclusively, the heat dissipation capacity of the first system cooling unit 33 takes about 20 percent of the overall heat dissipation capacity, and the heat dissipation capacity of the second system cooling unit 34 takes about 80 percent of the overall heat dissipation capacity.

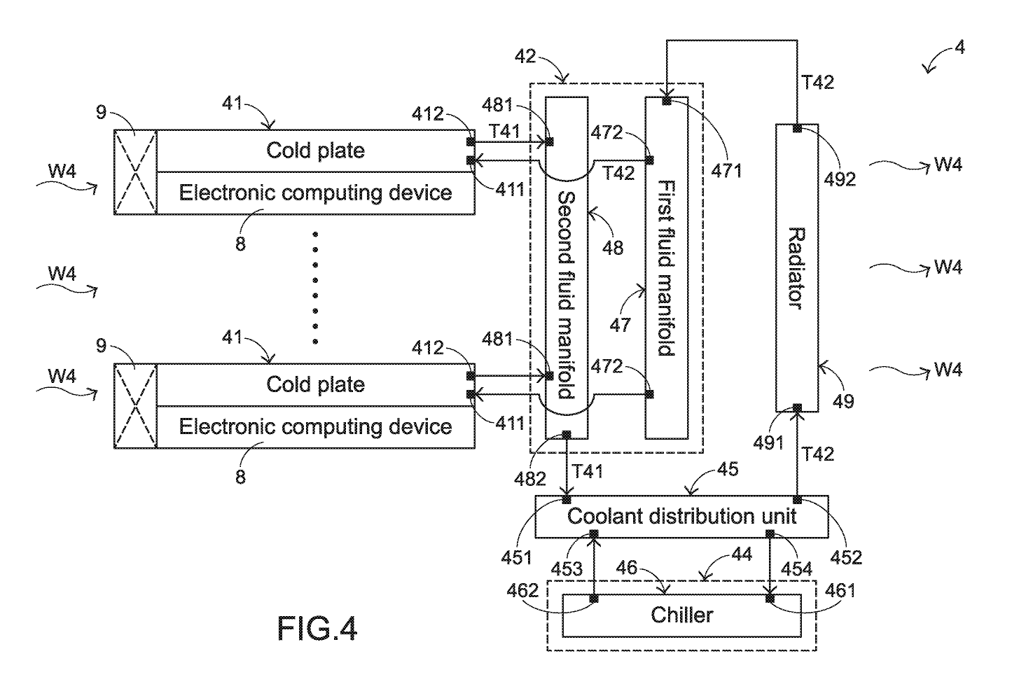

FIG. 4 schematically illustrates the architecture of a rack cooling system according to a fourth embodiment of the present invention.

As shown in FIG. 4, the rack cooling system 4 comprises plural cold plates 41, a manifold device 42, a radiator 49, a system cooling unit 44 and a coolant distribution unit (CDU) 45. The manifold device 42 comprises a first fluid manifold 47 and a second fluid manifold 48. The plural cold plates 41 correspond to plural electronic computing devices 8 in a rack (not shown). For example, the electronic computing devices 8 are servers or network storage devices. Each cold plate 41 is in contact with the heat source of the corresponding electronic computing device 8. Preferably but not exclusively, the cold plate 41 and the corresponding electronic computing device 8 are included in the same chassis (not shown). Each cold plate 41 comprises a cold plate inlet 411 and a cold plate outlet 412. The first fluid manifold 47 comprises a first manifold inlet 472 and plural first manifold outlets 472 corresponding to the plural cold plates 41. The second fluid manifold 48 comprises plural second manifold inlets 481 corresponding to the plural cold plates 41 and a second manifold outlet 482. The coolant distribution unit 45 comprises a first coolant distribution unit inlet 451, a first coolant distribution unit outlet 452, a second coolant distribution unit inlet 453 and a second coolant distribution unit outlet 454.

For example, the radiator 49 is a condenser. Preferably but not exclusively, the system cooling unit 44 comprises a chiller 46. The condenser is a heat exchanger for transforming gas or vapor into liquid so as to provide cooling efficacy. In addition, the heat from the heat pipe (not shown) of the condenser can be quickly radiated to the ambient air of the radiator 49. Consequently, the heat is dissipated away. The radiator 49 comprises a radiator inlet 491 and a radiator outlet 492. The chiller 46 comprises a chiller inlet 461 and a chiller outlet 462.

The cold plate inlet 411 of each cold plate 41 is in fluid communication with the corresponding first manifold outlet 472 of the first fluid manifold 47. The cold plate outlet 412 of each cold plate 41 is in fluid communication with the corresponding second manifold inlet 481 of the second fluid manifold 48. The first coolant distribution unit inlet 451 of the coolant distribution unit 45 is in fluid communication with the second manifold outlet 482 of the second fluid manifold 48. The first coolant distribution unit outlet 452 of the coolant distribution unit 45 is in communication with the radiator inlet 491 of the radiator 49. The radiator outlet 492 of the radiator 49 is in fluid communication with the first manifold inlet 471 of the first fluid manifold 47. In other words, a first fluid loop is defined by the plural cold plates 41, the manifold device 42, the coolant distribution unit 45 and the radiator 49 collaboratively.

Preferably but not exclusively, the relationship of each fluid communication may be established through the connection of an associated conduit (not shown). Moreover, a first fluid medium (not shown) is filled in the first fluid loop. The first fluid medium is a liquid medium, a gaseous medium or the mixture of the liquid medium and the gaseous medium. In the rack cooling system 4, the manifold device 42 is used for connecting associated conduits, homogenizing the first fluid medium and transferring the first fluid medium. After the first fluid medium is introduced into the coolant distribution unit 45, the first fluid medium is distributed by the coolant distribution unit 45. For example, the first fluid medium is uniformly or intelligently transferred from the coolant distribution unit 45 to the radiator 49 according to the practical requirements. Preferably but not exclusively, the coolant distribution unit 45 is capable of monitoring the heat dissipation performance in real time and automatically adjusting the optimal heat dissipation performance.

The chiller inlet 461 of the chiller 46 is in fluid communication with the second coolant distribution unit outlet 454 of the coolant distribution unit 45. The chiller outlet 462 of the chiller 46 is in fluid communication with the second coolant distribution unit inlet 453 of the coolant distribution unit 45. That is, a second fluid loop is defined by the chiller 46 and the coolant distribution unit 45 collaboratively. Moreover, a second fluid medium (not shown) is filled in the second fluid loop. The second fluid medium is a liquid medium, a gaseous medium or the mixture of the liquid medium and the gaseous medium. The chiller 46 may be considered as a cooling mechanism for removing the heat from the first fluid medium that is transferred through the first fluid loop. That is, the first fluid medium in the first fluid loop and the second fluid medium in the second fluid loop exchange heat in the coolant distribution unit 45, wherein the first fluid medium and the second fluid medium are not mixed together.

The operations of the rack cooling system 4 according to the fourth embodiment of the present invention will be described as follows. When the first fluid medium flows through the cold plate 41 along the first fluid loop, the first fluid medium is heated by the heat source of the electronic computing device 8 corresponding to the cold plate. After the heated first fluid medium is outputted from the cold plate 41 through the cold plate outlet 412, the first fluid medium is transferred to the second fluid manifold 48 through the corresponding second manifold inlet 481. After the first fluid medium is outputted from the second fluid manifold 48 through the second manifold outlet 482, the first fluid medium is transferred to the coolant distribution unit 45 through the first coolant distribution unit inlet 451. Similarly, when the second fluid medium flows through the coolant distribution unit 45 along the second fluid loop, the second fluid medium is heated by the first fluid medium that is introduced into the coolant distribution unit 45. After the heated second fluid medium is outputted from the coolant distribution unit 45 through the second coolant distribution unit outlet 454, the second fluid medium is transferred to the chiller 46 through the chiller inlet 461. Consequently, the second fluid medium is cooled down. After the second fluid medium is cooled down, the cooled second fluid medium is outputted from the chiller 46 through the chiller outlet 462. Moreover, the second fluid medium is transferred to the coolant distribution unit 45 again through the second coolant distribution unit inlet 453. Since the first fluid medium flowing into the coolant distribution unit 45 along the first fluid loop exchanges heat with the second fluid medium, the first fluid medium is cooled down.

After the first fluid medium flowing along the first fluid loop is cooled down by the coolant distribution unit 45, the first fluid medium is outputted from the coolant distribution unit 45 through the coolant distribution unit outlet 452. Then, the first fluid medium is transferred to the radiator 49 through the radiator inlet 491. After the first fluid medium is outputted from the radiator 49 through the radiator outlet 49, the first fluid medium is transferred to the first fluid manifold 47 through the first manifold inlet 471. After the first fluid medium is outputted from the first fluid manifold 47 through the first manifold outlet 472, the fluid medium is transferred to the cold plate 41 again through the corresponding cold plate inlet 411. The above steps are repeatedly done to circulate the first fluid medium along the first fluid loop and circulate the second fluid medium along the second fluid loop. Since the heat of the electronic computing device 8 is dissipated to the low-temperature site, the efficacy of reducing the temperature of the first fluid medium is enhanced

In the fourth embodiment, the rack cooling system comprises plural fans 9 corresponding to the plural electronic computing devices 8. For example, the plural fans 9 are arranged near the plural electronic computing devices 8. The airflow W4 driven by each fan 9 facilitates removing at least a portion of the heat from the corresponding plural electronic computing device 8. Consequently, the ambient air is heated. As mentioned above, the radiator 49 is capable of reducing the temperature of the ambient air. Consequently, the temperature of the heated airflow is reduced by the radiator 49. Since the overall temperature of the environment around the rack cooling system 4 is reduced, the efficacy of dissipating the heat of the air is achieved.

For example, after the first fluid medium is outputted from the cold plate 41 and before the first fluid medium is introduced into the coolant distribution unit 45, the fluid medium has an average temperature T41. After the first fluid medium is outputted from the coolant distribution unit 45 and before the first fluid medium is transferred to the cold plate 41, the first fluid medium has an average temperature T42. Consequently, the average temperature T42 is lower than the average temperature T41.

In comparison with the conventional rack cooling system 7, the rack cooling system 4 of the fourth embodiment is further equipped with the radiator 49 and the plural fans 9 to cool the ambient air. In other words, the rack cooling system 4 of this embodiment is suitably installed in the rack with higher heat dissipation demand.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

1. A rack cooling system for a rack, plural electronic computing devices being installed in the rack, the rack cooling system comprising:
plural cold plates corresponding to the plural electronic computing devices;
a radiator, wherein a first fluid medium flows through the radiator to exchange heat;
a coolant distribution unit in fluid communication with the radiator, wherein after the first fluid medium is introduced into the coolant distribution unit, the first fluid medium is distributed by the coolant distribution unit;
at least one fan driving an airflow;
a manifold device in fluid communication with the plural cold plates, the radiator and the coolant distribution unit, respectively, such that the plural cold plates, the radiator, the coolant distribution unit and the manifold device form a first fluid loon, wherein the first fluid loop is filled with the first fluid medium, and the first fluid medium is circulated through the plural cold plates, the radiator, the coolant distribution unit and the manifold device, so that the heat from the plural electronic computing devices is dissipated away;
a chiller in fluid communication with the coolant distribution such that the chiller and the coolant distribution unit form a second fluid loop, where the second fluid loop is filled with a second fluid medium, and the second fluid medium is circulated through the chiller and the coolant distribution unit, so that the second fluid medium exchanges heat with the first fluid medium circulated through the coolant distribution unit, wherein the first fluid medium and the second fluid medium are not mixed together.

2. The rack cooling system according to claim 1, wherein the manifold device comprises a first fluid manifold and a second fluid manifold, wherein the first fluid manifold comprises a first manifold inlet and plural first manifold outlets corresponding to the plural cold plates, and the second fluid manifold comprises a second manifold outlet and plural second manifold inlets corresponding to the plural cold plates.

3. The rack cooling system according to claim 2, wherein each of the plural cold plates comprises a cold plate inlet and a cold plate outlet, wherein the cold plate inlet is in fluid communication with the corresponding one of the plural first manifold outlets, and the cold plate outlet is in fluid communication with the corresponding one of the plural second manifold inlets, wherein after the first fluid medium is outputted from the cold plate through the cold plate outlet, the first fluid medium is transferred to the second fluid manifold through the corresponding one of the plural second manifold inlets, wherein after the first fluid medium is outputted from the first fluid manifold through the corresponding one of the plural first manifold outlets, the first fluid medium is transferred to the cold plate through the cold plate inlet.

4. The rack cooling system according to claim 3, wherein the radiator comprises a radiator inlet and a radiator outlet, and the coolant distribution unit comprises a first coolant distribution unit inlet and a first coolant distribution unit outlet, wherein the radiator inlet is in fluid communication with the second manifold outlet, the radiator outlet is in fluid communication with the first coolant distribution unit inlet, and the first coolant distribution unit outlet is in communication with the first manifold inlet, wherein after the first fluid medium is outputted from the second fluid manifold through the second manifold outlet, the first fluid medium is transferred to the radiator through the radiator inlet, wherein after the first fluid medium is outputted from the radiator through the radiator outlet, the first fluid medium is transferred to the coolant distribution unit through the first coolant distribution unit inlet, wherein after the first fluid medium is outputted from the coolant distribution unit through the first coolant distribution unit outlet, the first fluid medium is transferred to the first fluid manifold through the first manifold inlet.

5. The rack cooling system according to claim 3, wherein the radiator comprises a radiator inlet and a radiator outlet, and the coolant distribution unit comprises a first coolant distribution unit inlet and a first coolant distribution unit outlet, wherein the radiator inlet is in fluid communication with the first coolant distribution unit outlet, the radiator outlet is in fluid communication with the first manifold inlet, and the first coolant distribution unit inlet is in communication with the second manifold outlet, wherein after the first fluid medium is outputted from the second fluid manifold through the second manifold outlet, the first fluid medium is transferred to the coolant distribution unit through the first coolant distribution unit inlet, wherein after the first fluid medium is outputted from the coolant distribution unit through the first coolant distribution unit outlet, the first fluid medium is transferred to the radiator through the radiator inlet, wherein after the first fluid medium is outputted from the radiator through the radiator outlet, the first fluid medium is transferred to the first fluid manifold through the first manifold inlet.

6. The rack cooling system according to claim 1, wherein the chiller comprises a chiller inlet and a chiller outlet, and the coolant distribution unit comprises a second coolant distribution unit inlet and a second coolant distribution unit outlet, wherein the chiller inlet is in fluid communication with the second coolant distribution unit outlet, and the chiller outlet is in fluid communication with the second coolant distribution unit inlet, wherein after a second fluid medium is outputted from the coolant distribution unit through the second coolant distribution unit outlet, the second fluid medium is transferred to the chiller through the chiller inlet, wherein after the second fluid medium is outputted from the chiller through the chiller outlet, the second fluid medium is transferred to the coolant distribution unit through the second coolant distribution unit inlet.

7. The rack cooling system according to claim 1, wherein the at least one fan is arranged near the radiator, or the at least one fan is arranged near the plural cold plates.

8. The rack cooling system according to claim 1, wherein after the first fluid medium is outputted from one of the plural cold plates and before the first fluid medium is introduced into the radiator, the first fluid medium has a first average temperature, wherein after the first fluid medium is outputted from the radiator and before the first fluid medium is transferred to the one of the plural cold plates, the first fluid medium has a second average temperature, wherein the first average temperature is higher than the second average temperature.

9. The rack cooling system according to claim 1, wherein after the first fluid medium is outputted from one of the plural cold plates and before the first fluid medium is introduced into the coolant distribution unit, the first fluid medium has a first average temperature, wherein after the first fluid medium is outputted from the coolant distribution unit and before the first fluid medium is transferred to the one of the plural cold plates, the first fluid medium has a second average temperature, wherein the first average temperature is higher than the second average temperature.

10. The rack cooling system according to claim 1, wherein each of the plural electronic computing devices is a server or a network storage device.

11. The rack cooling system according to claim 1, wherein the radiator is a condenser.
